(19) United States
(12) Patent Application Publication
(10) Pub. No.: US 2023/0014850 A1
(43) Pub. Date: Jan. 19, 2023

(54) FLIP-CHIP LIGHT-EMITTING DIODE AND SEMICONDUCTOR LIGHT-EMITTING DEVICE

(71) Applicant: Xiamen San'an Optoelectronics Co., Ltd., Xiamen (CN)

(72) Inventors: QING WANG, Xiamen (CN); MINYOU HE, Xiamen (CN); JIANGBIN ZENG, Xiamen (CN); SHIWEI LIU, Xiamen (CN); JIN XU, Xiamen (CN); XIAOLIANG LIU, Xiamen (CN); ZHANGGEN XIA, Xiamen (CN); LINGYUAN HONG, Xiamen (CN); BAOJUN SHI, Xiamen (CN); SHUIJIE WANG, Xiamen (CN); KE LIU, Xiamen (CN); DAZHONG CHEN, Xiamen (CN); CHUNGYING CHANG, Xiamen (CN)

(21) Appl. No.: 17/852,365

(22) Filed: Jun. 29, 2022

(30) Foreign Application Priority Data
Jul. 15, 2021 (CN) 2021108016309
Dec. 28, 2021 (CN) 2021116218872

(51) Int. Cl. H01L 33/46; H01L 33/52

(52) U.S. Cl. CPC H01L 33/46; H01L 33/52; H01L 33/0095

(57) ABSTRACT

A flip light-emitting diode (LED) and a semiconductor light-emitting device are provided. The flip-chip LED includes a substrate, a semiconductor stacking layer formed on a first surface of the substrate for radiating light, and an optical thin film stacking layer formed on a second surface of the substrate and including a first reflective film group. The first reflective film group includes a first material layer and a second material layer repeatedly stacked. Optical thicknesses of the first and second material layers meet: the first reflective film group reflects a light with a wavelength in a range from 420 nm to 480 nm and at an incident angle being a first angle, and partially transmits a light with the wavelength and at an incident angle being a second angle, and the first angle is smaller than the second angle. The brightness of the flip-chip LED can be improved.

### TECHNICAL FIELD

The disclosure relates to a field of semiconductor related technologies, in particularly to a flip-chip light-emitting diode (LED) and a semiconductor light-emitting device.

### BACKGROUND

In recent years, the backlight display field has put forward higher requirements for display effects of display devices; and submillimeter light-emitting diodes (Mini LEDs), as an improved version of traditional light-emitting diodes have been rapidly promoted, which can significantly improve the display effects of display devices.

The Mini LED needs to have a good light output effect. There are two methods to improve its light output effect. One is a flip-chip design of the Mini LED; and the other is to control a light output angle of the Mini LED and a size of the light output angle directly determines multiple optical performances of the Mini LED. An existing solution is the flip-chip design of Mini LED, which makes the Mini LED emit light from a side of a substrate, and coats a distributed Bragg reflection (DBR) layer on the substrate. The existing distributed Bragg reflection layer usually is formed by repeatedly stacked low refractive index material layer and high refractive index material layer. Through a thickness matching design of the material layers, for example, a design of a thin optical film stack with a thick optical film stack, the thin optical film stack has several pairs of a thin low refractive index material layer and a thin high refractive index material layer, the thick optical film stack has several pairs of a relatively thick low refractive index material layer and a relatively thick high refractive index material layer, and an optical thickness of each material layer is in a range of 100 nanometer (nm) to 150 nm, which can have a relatively large reflectivity for light radiated inside the Mini LED while preventing front light leakage of the Mini LED. For example, as shown in FIG. 15, the existing distributed Bragg reflection layer has a reflectivity of more than 90% for at least light with a light output angle of 0° to 60° in a wavelength range of 420 nm to 480 nm, which can promote the light to exit from sidewalls of the Mini LED, thereby achieving a large light output angle. However, repeated internal reflections are easy to lead to internal absorption, resulting in a loss of brightness of the Mini LED. Moreover, a thickness of the distributed Bragg reflection layer is relatively thick, usually is more than 2 microns (μm), and the number of layers is more than 20, which is prone to reduce a cutting yield and cause a high probability of edge and corner collapses.

### SUMMARY

A purpose of the disclosure is to provide a flip-chip LED, which can effectively improve brightness of a flip-chip LED, by optimizing material performances and a thickness of an optical thin film stacking layer located on a light-emitting side of a substrate, and realizing a relatively large reflectivity for output light in a relatively small angle and a relatively small reflectivity for output light in a relatively large angle while maintaining a large angle light output. In addition, a thickness design of the optical thin film stacking layer can also improve a yield of a flip-chip LED manufacturing process.

In a first aspect, a flip-chip LED is provided and includes: a substrate, having a first surface and a second surface opposite to the first surface; a semiconductor stacking layer, formed on the first surface and configured to radiate light; and an optical thin film stacking layer, formed on the second surface; the optical thin film stacking layer including a first reflective film group, the first reflective film group including a first material layer and a second material layer repeatedly stacked; optical thicknesses of the first material layer and the second material layer meeting conditions that: the first reflective film group is configured to reflect a light with a wavelength in a range of 420 nm to 480 nm and at an incident angle being a first angle, and partially transmit a light with the wavelength and at an incident angle being a second angle, and the first angle being smaller than the second angle.

In a second aspect, a flip-chip LED is provided and includes: a substrate, having a first surface and a second surface opposite to the first surface; a semiconductor stacking layer, formed on the first surface and configured to radiate light; and an optical thin film stacking layer, formed on the second surface; the optical thin film stacking layer including a first reflective film group and a second reflective film group, the second reflective film group is disposed on a side of the first reflective film group facing away from the second surface; the first reflective film group including a first material layer with a relatively high refractive index and a second material layer with a relatively low refractive index repeatedly stacked; the second reflective film group including a third material layer with a relatively low refractive index and a fourth material layer with a relatively high refractive index repeatedly stacked; and a geometric thickness of each the second material layer with the relatively low refractive index in the first reflective film group being smaller than that of each the third material layer with the relatively low refractive index in the second reflective film group.

In a third aspect, a preparation method of a flip-chip LED is provided and includes the following steps: providing a substrate, the substrate having a first surface and a second surface opposite to the first surface; forming a plurality of semiconductor stacking layers arranged at intervals on the first surface of the substrate, and forming a cutting channel between every adjacent two of the plurality of semiconductor stacking layers; forming an optical thin film stacking layer on the second surface of the substrate; and performing stealth cutting on the flip-chip LED along the cutting channels, the cutting including providing laser light in a range of 600 nm to 700 nm, providing laser light in a range of 800 nm to 900 nm and providing laser light in a range of 1000 nm to 1100 nm, and making the above laser light enter an interior of the substrate from the second surface of the substrate.

In a fourth aspect, a semiconductor light-emitting device is provided and includes: a packaging substrate; a flip-chip LED, arranged on the packaging substrate; and a packaging layer, disposing covering sidewalls of the flip-chip LED; the flip-chip LED including: a substrate, having a first surface and a second surface opposite to the first surface; a semiconductor stacking layer, formed on the first surface and configured to radiate light; and an optical thin film stacking layer, formed on the second surface; the optical thin film stacking layer including a first reflective film group, and the first reflective film group including a first material layer and a second material layer repeatedly stacked; optical thicknesses of the first material layer and the second material layer meeting conditions that: the first reflective film group is configured to reflect a light with a wavelength in a range of 420 nm to 480 nm and at an incident angle being a first angle, and partially transmit a light with the wavelength and at an incident angle being a second angle, and the first angle being smaller than the second angle.

### BRIEF DESCRIPTION OF THE DRAWINGS

FIG. 1 illustrates a schematic structural view of a flip-chip LED according to an embodiment of the disclosure.

FIG. 2 illustrates a schematic structural view of an optical thin film stacking layer according to an embodiment of the disclosure.

FIG. 3 illustrates a schematic structural view of an optical thin film stacking layer according to another embodiment of the disclosure.

FIG. 4 illustrates a schematic view of optical thickness settings of an optical thin film stacking layer according to an embodiment of the disclosure.

FIG. 5 illustrates a schematic view of geometric thickness settings of an optical thin film stacking layer according to an embodiment of the disclosure.

FIG. 6 illustrates a schematic view of reflectivities of an optical thin film stacking layer according to an embodiment of the disclosure.

FIG. 7 illustrates a schematic view of reflectivities of a first reflective film group and a second reflective film group according to an embodiment of the disclosure.

FIG. 8 illustrates a schematic view of reflectivities of a first reflective film group for different angles of light according to an embodiment of the disclosure.

FIG. 9 illustrates a schematic structural view of a semiconductor light-emitting device according to an embodiment of the disclosure.

FIGS. 10 through 14 illustrate schematic structural views of a flip-chip LED at different preparation stages according to an embodiment of the disclosure.

FIG. 15 illustrates a schematic view of reflectivities of an existing distributed Bragg reflective layer for different angles of light.

### DETAILED DESCRIPTION OF THE EMBODIMENTS

According to an aspect of the disclosure, a flip-chip LED is provided. The flip-chip LED is a submillimeter LED (Mini LED) with a flip-chip structure, and a size of the Mini LED can be within 90000 square microns (μm²), a length and a width of the Mini LED each are in a range from 50 μm to 300 μm, a height of the Mini LED is in a range from 60 μm to 150 μm.

As illustrated in FIG. 1, the flip-chip LED may include a substrate 200, a semiconductor stacking layer 300, and an optical thin film stacking layer 100.

A thickness of the substrate 200 may be in a range from 60 μm to 150 μm, and a thickness of the semiconductor stacking layer 300 may be in a range from 3 μm to 10 μm.

The substrate 200 may be a transparent substrate, which may include but not be limited to a sapphire planar substrate or a sapphire patterned substrate. The substrate 200 has a first surface and a second surface opposite to the first surface, the first surface may refer to a lower surface of the substrate 200, and the second surface may refer to an upper surface of the substrate 200.

The semiconductor stacking layer 300 may be formed on the first surface and configured (i.e., structured and arranged) to radiate light. In an embodiment, the flip-chip LED may be used as a backlight source of a liquid crystal display (LCD) device. A wavelength range of the radiated light preferably is in a range from 420 nm to 480 nm, and a peak wavelength may be in a range from 440 nm to 455 nm.

The semiconductor stacking layer 300 may include a first semiconductor layer 310, an active layer 320 and a second semiconductor layer 330 from top to bottom. In the illustrated embodiment, the first semiconductor layer 310 is an N-type semiconductor layer, the second semiconductor layer 330 is a P-type semiconductor layer, and the active layer 320 is a multiple quantum well (MQW) layer and configured to emit light with a wavelength in a range from 420 nm to 480 nm.

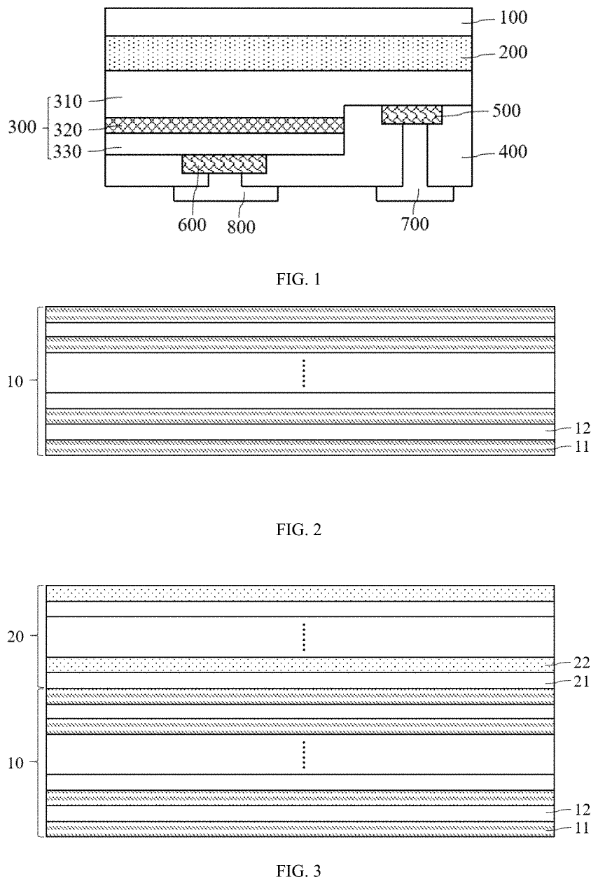

The optical thin film stacking layer 100 may be formed on the second surface. As shown in FIG. 2, the optical thin film stacking layer 100 includes a first reflective film group 10.

The first reflective film group 10 may include a first material layer 11 and a second material layer 12 repeatedly stacked. The first material layer 11 and the second material layer 12 may be alternately stacked from bottom to top, and refractive indexes of the first material layer 11 and the second material layer 12 are different. Optical thicknesses of the first material layer 11 and the second material layer 12 can meet that: for light radiated by the active layer, such as any light in a range of 420 nm to 480 nm, the first reflective film group 10 reflects the light emitted in a first angle, and partially transmits the light emitted in a second angle, and the first angle being smaller than the second angle.

In a preferred embodiment, for the light radiated by the active layer, such as the any light in the range of 420 nm to 480 nm, a reflectivity of the first reflective film group 10 to the light emitted in the first angle is greater than that of the first reflective film group 10 to the light emitted in the second angle.

For the light radiated by the active layer, such as the any light in the range of 420 nm to 480 nm, light in a small angle range is defined as light in the first angle, the first angle preferably is in a range of 0° to 20°. Since the first reflective film group 10 still reflects the light in the first angle, which can prevent light leakage from a front side of the flip-chip LED and improve a ratio of large angle light output. In a preferred embodiment, a reflectivity of the first reflective film group 10 to the light in the first angle is higher than 90%.

For the light radiated by the active layer, such as the any light in the range of 420 nm to 480 nm, light in a large angle range is defined as light in the second angle, and the first reflection film group 10 partially transmits the light in the large angle. For example, the first reflective film group 10 can adjust light in an angle of more than 30°, so as to improve a light efficiency of the flip-chip LED. For example, the second angle can be in a range of 40° to 60°, or even in a range of 40° to 50° or 50° to 60°. A reflectivity of the first reflective film group 10 to at least part of the light in the second angle is less than 90%, or even less than 80%, or less than 70%, or less than 60%.

Due to a total reflection phenomenon caused by a difference of material refractive index between the substrate 200 and the optical thin film stacking layer 100, the first reflective film group 10 is difficult to adjust a transmission ratio of light in an angle of more than 60°. Therefore, it is preferable that the second angle is no more than 60°.

In order to realize that light within the wavelength range of 420 nm to 480 nm emitted in a small angle has a high reflectivity and light within the wavelength range of 420 nm to 480 nm emitted in a large angle has a high transmission ratio, a thickness-wise stack of the first reflective film group 10 proposed in the disclosure may have the following characteristics:
the first material layer 11 is a high refractive index material layer, and the second material layer 12 is a low refractive index material layer.

The first material layer 11 preferably is a titanium oxide layer with a refractive index in a range of 2.4 to 2.6, and a geometric thickness of each first material layer 11 preferably is no more than 60 nm, and more preferably is in a range of 30 nm to 50 nm. An optical thickness of each first material layer 11 may be λ₁/4, 300 nm≤λ₁≤480 nm, and the optical thickness of each first material layer 11 preferably is in a range of 75 nm to 120 nm. The geometric thickness of the first material layer 11 cannot be excessively thin, if it is excessively thin, film quality of the first material layer 11 will be affected; and on the other hand, the geometric thickness of the first material layer 11 cannot be excessively thick, due to the light absorption phenomenon of the titanium oxide layer, if it is excessively thick, the reflectivity of the first reflective film group 10 will be decreased.

The second material layer 12 preferably is a silicon oxide layer with a refractive index in a range of 1.4 to 1.5. A geometric thickness of each second material layer 12 preferably does not exceed 100 nm, and more preferably is in a range of 60 nm to 100 nm. An optical thickness of each second material layer 12 may be λ₂/4, 350 nm≤λ₂≤520 nm, and the optical thickness of each second material layer 12 preferably is in a range of 85 nm to 140 nm.

In a preferred embodiment, the geometric thickness of each first material layer 11 is smaller than that of each second material layer 12.

In a preferred embodiment, in order to at least maintain the light in the wavelength range of 420 nm to 480 nm and emitted in the angle range of 0° to 20° has high reflectivity, a total geometric thickness of the first reflective film group 10 is no less than 500 nm, and a total layer number of the first reflective film group 10 is no less than 10.

In a preferred embodiment, a total geometric thickness of the second material layers 12 in the first reflective film group 10 does not exceed 1000 nm. More preferably, the total geometric thickness of the first reflective film group 10 does not exceed 1500 nm. A total layer number of the first material layers 11 and the second material layers 12 in the first reflective film group 10 is odd, and the total layer number does not exceed 15.

The first reflective film group 10 has a relatively thin total thickness and a relatively small total layer number, especially regulating the thickness of the second material layer 12 within the above range, which can realize the high reflectivity of the small angle light in the wavelength range of 420 nm to 480 nm and the relatively high transmittance of the large angle light, improving the brightness of the flip-chip LED.

In addition, the first reflective film group 10 maintains a relatively thin thickness or a relatively small total layer number, which can maintain the stability of the flip-chip LED and reduce the risk of edge collapse, corner collapse and abnormal crack caused by an excessive thickness of the first reflective film group 10.

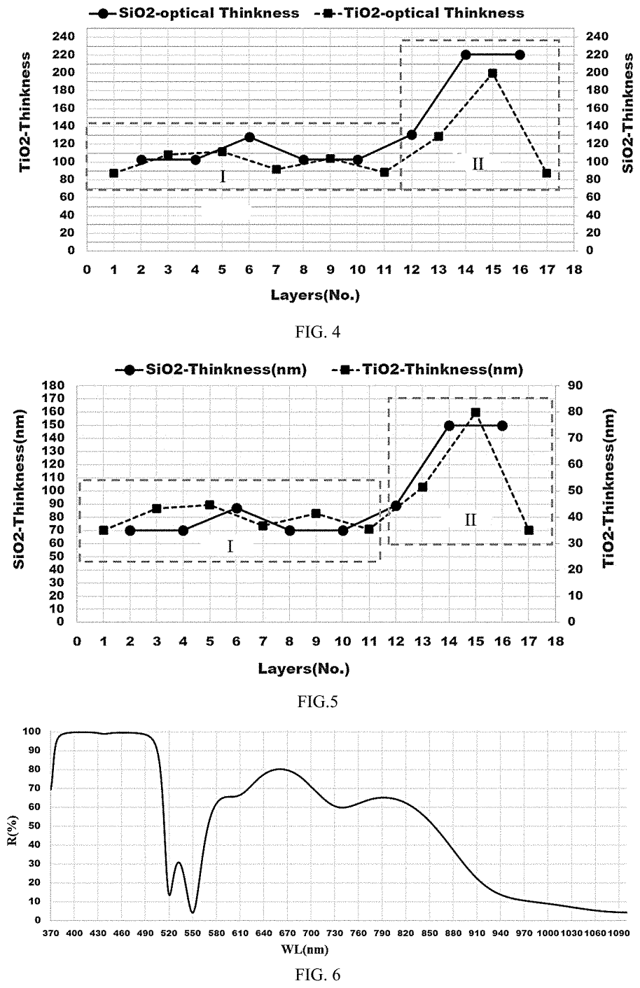

In an embodiment, as shown in FIG. 4 and FIG. 5, a region I in FIG. 4 illustrates optical thicknesses of the first reflective film group 10, and a region I in FIG. 5 illustrates geometric thicknesses of the first reflective film group 10.

Layer structures in the first reflective film group 10 are defined as a first layer, a second layer, . . . , and an Nth layer from bottom to top according to a stacking order. The odd layer structures each are the first material layer 11, and the even layer structure each are the second material layer 12. In other words, the first layer and the last layer of the first reflective film group 10 each are the first material layer 11, and the first and last layers of the optical thin film stacking layer 100 each are the first material layer 11.

The first layer of the optical thin film stacking layer 100 is directly formed on the substrate 200 and is the first material layer 11, which can prevent the problems of edge collapse and corner collapse of LED in a stealth cutting process. The last layer is also the first material layer 11 and has a large refractive index difference with respect to a packaging layer, and therefore can further improve the reflection effect and reduce light leakage from a front side of a semiconductor light-emitting device.

For example, the total layer number of the first material layers 11 and the second material layers 12 preferably is 11, the first, third, fifth, seventh, ninth and eleventh layers each are the first material layer 11; and the second, fourth, sixth, eighth and tenth layers each are the second material layer 12. The geometric thicknesses of the first material layers 11 are that: the geometric thickness of the first layer is 35 nm, the geometric thickness of the third layer is 43.35 nm, the geometric thickness of the fifth layer is 44.78 nm, the geometric thickness of the seventh layer is 36.78 nm, the geometric thickness of the ninth layer is 41.52 nm and the geometric thickness of the eleventh layer is 35.39 nm. The optical thicknesses of the first material layers 11 are that: the optical thickness of the first layer is 87.5 nm, the optical thickness of the third layer is 108.375 nm, the optical thickness of the fifth layer is 111.95 nm, the optical thickness of the seventh layer is 91.95 nm, the optical thickness of the ninth layer is 103.8 nm and the optical thickness of the eleventh layer is 88.475 nm. The geometric thicknesses of the second material layers 12 are that: the geometric thickness of the second layer is 70 nm, the geometric thickness of the fourth layer is 70nm, the geometric thickness of the sixth layer is 87.25 nm, the geometric thickness of the eighth layer is 70.01 nm and the geometric thickness of the tenth layer is 70.01 nm. The optical thicknesses of the second material layers 12 are that: the optical thickness of the second layer is 102.9 nm, the optical thickness of the fourth layer is 102.9 nm, the optical thickness of the sixth layer is 128.3 nm, the optical thickness of the eighth layer is 102.9 nm and the optical thickness of the tenth layer is 102.9 nm.

FIG. 8 illustrates a schematic view of reflectivities of the first reflective film group 10 for different angles of light by measuring full light in the range of 420 nm to 480 nm. It can be seen from FIG. 8 that for the light in the wavelength range of 420 nm to 480 nm, a reflectivity curve moves to the left with the increase of the angle; that is, the reflectivity of the first reflective film group 10 for the light in the wavelength range of 420 nm to 480 nm decreases with the increase of the angle. Specifically, when the angle is any one 10°, 20° and 30°, the reflectivity of the first reflective film group 10 to the light in the wavelength range of 420 nm to 480 nm is greater than or equal to 97%. When the angle is 40°, the reflectivity of the first reflective film group 10 to a part of the light in the wavelength range of 420 nm to 480 nm is less than 90%, but greater than or equal to 60%. When the angle is 50°, the reflectivity of the first reflective film group 10 to a part of the light in the wavelength range of 420 nm to 480 nm, especially in the wavelength range of 460 nm to 480 nm, is less than 90%, but is greater than or equal to 40%. When the angle is 60°, the reflectivity of the first reflective film group 10 to the light in the wavelength range of 420 nm to 480 nm, especially in the range of 440 nm to 480 nm or 440 nm to 455 nm is less than 90%, for example, it can be in a range between 30% and 90%. As seen from FIG. 8 that the part of the light with larger angle in the range of 420 nm to 480 nm, especially the part of light with the angle in the range of 40°˜60°, has been transmitted out.

In a preferred embodiment, taking 450 nm as a peak wavelength and a reflectivity of light at 450 nm for calculation, a reflectivity of the first reflective film group 10 to the light at 450 nm with an angle of 50° is greater than 60%, and preferably is greater than or equal to 90%. A reflectivity of the first reflective film group 10 to the light at 450 nm with an angle of 60° is less than or equal to 70%, and preferably is less than or equal to 60%.

Compared with a traditional distributed Bragg reflective (DBR) layer, the optical thin film stacking layer 100 employing the above first reflective film group 10 has a greater reflectivity for the small angle light output from the semiconductor stacking layer 300 and a less reflectivity for the large angle light output from the semiconductor stacking layer 300, and therefore can ensure that the flip-chip LED has higher brightness. For example, under a driving current of 1 milliampere (mA), the brightness of the flip-chip LED can be increased by 6%˜7%; and under a driving current of 12 mA, the brightness of the flip-chip LED can be increased by 3.5%˜4%.

In an embodiment, as shown in FIG. 6, in order to ensure a transmission effect of some large angle light in the range of 420 nm to 480 nm, the thickness of the first reflective film group 10 needs not be excessively thick and has a relatively low reflectivity at least for light with an angle of 0° to 10° in the range of 520 nm to 600 nm, specifically the low reflectivity is less than 90%, or even less than 80%.

In another embodiment, since the substrate of an existing small-size flip-chip LED usually is relatively thin, it is easy to cause warpage and unevenness of the whole flip-chip LED before separation, thereby resulting in a laser with a wavelength in a range between 1000 nm and 1100 nm being easy to deviate from target thickness positions in the substrate during stealth cutting, and the failure of the stealth cutting.

The disclosure proposes to further optimize the optical thin film stacking layer, which can improve the consistency of cutting thickness-wise positions of a substrate in a flip-chip LED, thereby optimizing the cutting yield.

Specifically, as illustrated in FIG. 3, the optical thin film stacking layer 100 may further include a second reflective film group 20, which is formed on the first reflective film group 10 along the stacking direction of the first reflective film group 10, and thereby the second reflective film group 20 is farther away from the substrate 200 than the first reflective film group 10.

The second reflective film group 20 has a relatively high reflectivity to a first light, and the reflectivity preferably is higher than 50%. The first light preferably is laser light, and a wavelength range thereof in a range of 600 nm to 700 nm and a center wavelength is 650 nm. The first light can be applied to a separation step of the flip-chip LED, so as to reduce the risk of reduction of the cutting yield caused by deviation of a laser with a wavelength in the range of 1000 nm to 1100 nm from the target thickness positions inside the substrate during the stealth cutting.

For example, the reflectivity of the second reflective film group 20 to the light with the center wavelength of 650 nm and in an angle range of 0° to 10° is higher than 50%, which is convenient to accurately position dotting positions of the laser on the substrate 200 by using the first light with the center wavelength of 650 nm, thereby improving the accuracy of the stealth cutting process.

The second reflective film group 20 may further have a relatively low reflectivity to a second light, and the reflectivity preferably is less than 60%. A center wavelength of the second light is in a range of 800 nm to 900 nm, and the center wavelength preferably is 850 nm. The second light can pass through the optical thin film stacking layer 100 to obtain an image (e.g., charge coupled device (CCD) imaging) of the semiconductor stacking layer 300 and electrode structures on the other side of the substrate 200. For example, a reflectivity of the second reflective film group 20 to the light with the center wavelength of 850 nm and in the angle range of 0° to 10° is less than 60%.

The second reflective film group 20 may further have a relatively low reflectivity to a third light, and the reflectivity preferably is less than 10%. The third light preferably is laser light, and its center wavelength is in a range from 1000 nm to 1100 nm, and the center wavelength preferably is 1064 nm. The third light can pass through the optical thin film stacking layer 100 and then reach the interior of the substrate 200 to form modified regions. By applying an external force along the modified regions, the substrate 200 can be separated in pieces to obtain individual flip-chip LEDs. For example, the reflectivity of the second reflective film group 20 to the light with the center wavelength of 1064 nm and in the angle range of 0° to 10° is less than 10%.

In an embodiment, the second reflective film group 20 may include a third material layer 21 and a fourth material layer 22 repeatedly stacked, and the third material layer 21 and the fourth material layer 22 are alternately stacked from bottom to top. The third material layer 21 may be a low refractive index material layer, and the fourth material layer 22 may be a high refractive index material layer.

Specifically, optical thicknesses of the third material layer 21 and the fourth material layer 22 can meet that: the second reflective film group 20 reflects the first light and transmits the second light and the third light, the reflectivity of the second reflective film group 20 to the first light is greater than 50%, the reflectivity of the second reflective film group 20 to the second light is less than 60%, and the reflectivity of the second reflective film group 20 to the third light is less than 10%. Incident angles of the first light, the second light and the third light each are in a range of 0° to 10°.

In order to meet reflection or transmission requirements of the respective light in stealth cutting, in the second reflective film group 20, the third material layer 21 and the fourth material layer 22 are stacked repeatedly, and the refractive index of the fourth material layer 22 is greater than that of the third material layer 21. The number of the third material layer 21 or the fourth material layer 22 is of 2 to 5 layers. A geometric thickness of each third material layer 21 of the second reflective film group 20 is greater than that of each second material layer 12 of the first reflective film group 10, to ensure the reflectivity for light at 650 nm.

In a preferred embodiment, in the second reflective film group 20, a total layer number of the third material layers 21 and the fourth material layers 22 is even, and the total layer number is less than 10. The total layer number of the second reflective film group 20 should not be too large, and preferably is lower than the total layer number of the first reflective film layer 10. If the total layer number of the second reflective film group 20 is too large, which would lead to the optical thin film stacking layer 100 has large reflectivities to the second light and the third light, especially to the third light, so that the energy of the stealth cutting is reduced and thus the stealth cutting is degraded. When the total layer number of the second reflective film group 20 is too large, it will also affect the transmission effect of the optical thin film stacking layer 100 on some large angle light in the wavelength range of 420 nm to 480 nm.

In a preferred embodiment, the total geometric thickness of the second reflective film group 20 does not exceed 800 nm. More preferably, the total geometric thickness of the second reflective film group 20 is lower than that of the first reflective film group 10.

In a preferred embodiment, the third material layer 21 preferably is a silicon oxide layer with a refractive index in a range of 1.4 to 1.5, the geometric thickness of each third material layer 21 is in a range of 80 nm to 160 nm, and the optical thickness of each third material layer 21 is λ₃/4, and 450 nm≤λ₃≤900 nm. The optical thickness of each third material layer 21 preferably is in a range from 120 nm to 210 nm. The fourth material layer 22 preferably is a titanium oxide layer with a refractive index in a range of 2.4 to 2.6, the geometric thickness of each fourth material layer 22 is in a range of 30 nm to 90 nm, and the optical thickness of each fourth material layer 22 is λ₃/4, and 300 nm≤λ₄/900 nm . The optical thickness of each fourth material layer 22 preferably is in a range of 80 nm to 200 nm.

In a preferred embodiment, the geometric thickness of each fourth material layer 22 is lower than that of each third material layer 21.

In a preferred embodiment, the material of the fourth material layer 22 is the same as that of the first material layer 11, and the material of the third material layer 21 is the same as that of the second material layer 12.

In a preferred embodiment, the geometric thickness of each first material layer 11 with relatively high refractive index in the first reflective film group 10 is lower than that of each fourth material layer 22 with relatively high refractive index in the second reflective film group 20.

In a preferred embodiment, the total geometric thickness of the second material layers 12 of the first reflective film group 10 is lower than that of the third material layers 21 of the second reflective film group 20.

In a preferred embodiment, the geometric thickness of each second material layer 12 of the first reflective film group 10 is lower than that of each third material layer 21 of the second reflective film group 20.

In an embodiment, as shown in FIGS. 4 and 5, a region II in FIG. 4 illustrates the optical thicknesses of the second reflective film group 20, and a region II in FIG. 5 illustrates the geometric thicknesses of the second reflective film group 20.

Layer structures of the second reflective film group 20 are defined as a (N+1)th layer, a (N+2)th layer, . . . , a (N+M)th layer from bottom to top according to the stacking order. The layer structure corresponding to M being an odd number is the third material layer 21, and the layer structure corresponding to M being an even number is the fourth material layer 22.

For example, the total layer number of the third material layers 21 and the fourth material layers 22 preferably is 6, N preferably is 11, and M preferably is 6. The twelfth, fourteenth and sixteenth layers each are the third material layer 21, and the thirteenth, fifteenth and seventeenth layers each are the fourth material layer 22. The geometric thicknesses of the third material layers 21 are that: the geometric thickness of the twelfth layer is 89.16 nm, the geometric thickness of the fourteenth layer is 150 nm, and the geometric thickness of the sixteenth layer is 150 nm. The optical thicknesses of the third material layers 21 are that: the optical thickness of the twelfth layer is 131.06 nm, the optical thickness of the fourteenth layer is 220.5 nm and the optical thickness of the sixteenth layer is 220.5 nm. The geometric thicknesses of the fourth material layers 22 are that: the geometric thickness of the thirteenth layer is 51.51 nm, the geometric thickness of the fifteenth layer is 80 nm, and the geometric thickness of the seventeenth layer is 35 nm. The optical thicknesses of the fourth material layers 22 are that: the optical thickness of the thirteenth layer is 128.775 nm, the optical thickness of the fifteenth layer is 200 nm and the optical thickness of the seventeenth layer is 87.5 nm.

In a preferred embodiment, a reflectivity of the second reflective film group 20 to the light at 650 nm is greater than or equal to 50%, and is not necessarily higher than 90%. The reflectivity of the second reflective film group 20 to the light at 650 nm preferably is greater than or equal to 70%, which is convenient to accurately position dotting positions of laser on the substrate 200 in a stealth cutting process by using the 650 nm of laser and thereby improve the accuracy of the stealth cutting process. The above 650 nm of laser mainly uses a laser ranging principle to calculate a thickness of the flip-chip LED, and determines the dotting positions of laser on the substrate 200 in the stealth cutting process according to the above thickness, thereby ensuring the consistency of the dotting position of laser on the substrate 200.

In a preferred embodiment, the reflectivity of the second reflective film group 20 to the light at 850 nm is less than or equal to 60%, which facilitates the light at 850 nm to pass through the optical thin film stacking layer 100 and obtain the image of the semiconductor stacking layer 300 and electrode structures on the other side of the substrate 200.

In a preferred embodiment, the reflectivity of the second reflective film group 20 to the light at 1064 nm is less than or equal to 10%, which facilitates the 1064 nm of laser to pass through the optical thin film stacking layer 100 and reach the interior of the substrate 200 for cutting.

In an embodiment, the second reflective film group 20 may include: along its stacking direction, a bottom layer, an intermediate layer, and a repeated stacking layer of two materials.

The intermediate layer is located below the repeated stacking layer and is a film layer with better compactness than each layer in a repeated stacking layer, which can form compact protection for the first reflective film group 10, and prevent external water vapor penetrating through the repeated stacking layer from reaching the first reflective film group 10 to damage performance, thereby improving high-temperature and high-humidity aging test performance. The intermediate layer preferably uses an atomic layer deposition (ALD) process or a sputter coating process to obtain the film layer with good compactness.

In a preferred embodiment, the intermediate layer is an alumina layer, and the third material layer 21 and the fourth material layer 22 are stacked repeatedly to form the repeated stacking layer of two materials.

In a preferred embodiment, the bottom layer is configured to avoid during the manufacturing process of the intermediate layer of alumina, the employment of the ALD or sputter coating would cause damage to the first reflective film group 10 and thereby result in the degradation of the flip-chip LED in performance. The bottom layer can be formed by an ALD or a PECVD (plasma enhanced chemical vapor deposition) or a sputter coating process, so as to ensure the compactness and high quality of the whole second reflective film group 20.

In a preferred embodiment, in order to ensure the compactness effect, a geometric thickness of the intermediate layer is at least 50 nm and at most 300 nm, and more preferably, the geometric thickness of the intermediate layer is in a range of 80 nm to 150 nm. A more thicker intermediate layer would reduce the efficiency of an etching process because of its difficulty of etching.

In a preferred embodiment, the bottom layer of the second reflective film group 20 is a silicon oxide layer, and the silicon oxide layer can be formed by an ALD or a sputter coating process. The compactness of the bottom layer of silicon oxide is lower than that of the intermediate layer of alumina. In a preferred embodiment, a geometric thickness of the bottom layer is at least 5 nm to form a continuous film layer. The geometric thickness of the bottom layer shall be at most 30 nm, and the geometric thickness of the bottom layer shall not be too thick, otherwise it will affect the compact protection effect of the alumina to the first reflective film group 10.

In an embodiment, a refractive index of the bottom layer is lower than that of the intermediate layer, and the refractive index of the intermediate layer is between the refractive indexes of the repeatedly stacked two material layers.

In a preferred embodiment, the second reflective film group 20 may further include a top layer, which also plays a protective role and can prevent external water vapor from passing through the repeated staking layer with poorer compactness. In a preferred embodiment, a compactness of the top layer is higher than each material layer of the repeated stacking layer, a material of the top layer is alumina or silicon oxide, the top layer can be formed by PECVD or sputter coating; and more preferably, the top layer is an alumina layer, and the alumina has relatively high compactness. A geometric thickness of the top layer is at least 50 nm and at most 300 nm, and more preferably is in a range of 80 nm to 150 nm. A more thicker top layer would reduce the efficiency of an etching process resulting from its difficulty of etching.

It should be noted that materials of the top layer and the intermediate layer both have high compactness, and the top layer and the intermediate layer can be set either or together. Compared with the intermediate layer, the top layer is farther away from the semiconductor stacking layer 300, but the protective effect is not as good as the intermediate layer.

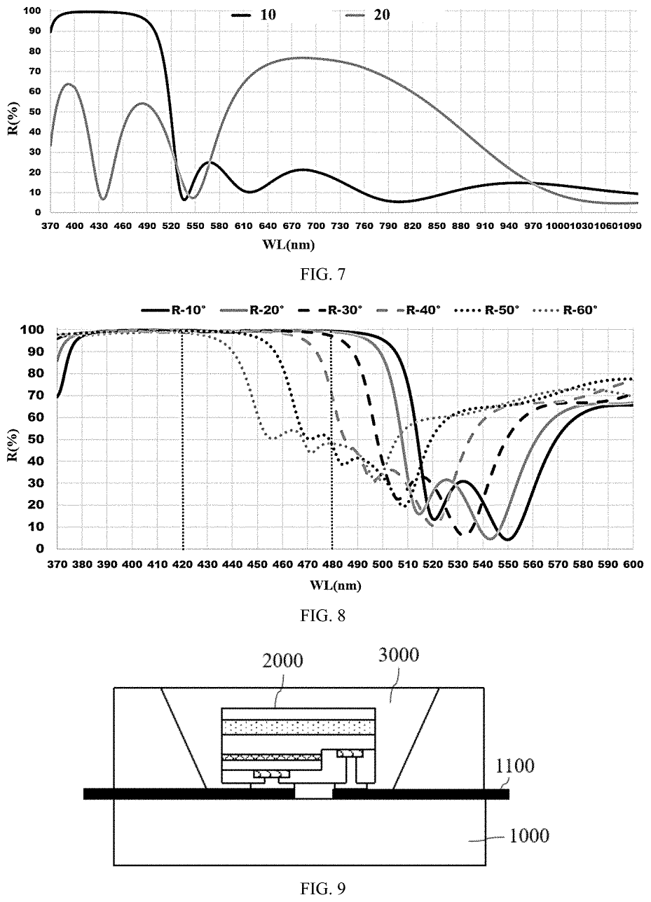

As shown in FIG. 6 and FIG. 7, the reflectivity of the second reflective film group 20 to the light with an angle of 10° in the range of 600 nm to 700 nm is in a range of 60% to 80%, the reflectivity of the second reflective film group 20 to the light with an angle of 10° in the range of 800 nm to 900 nm is less than 60%, and the reflectivity of the second reflective film group 20 to the light with an angle of 10° in the range of 1000 nm to 1100 nm is less than 10%.

In a preferred embodiment, the first layer of the optical thin film stacking layer 100 is the first layer of the first reflective film group 10 and is a titanium oxide layer, which can prevent the problems of edge collapse and corner collapse of the LED in a stealth cutting process; and the last layer of the optical thin film stacking layer 100 is the last layer of the second reflective film group 20 and is a titanium oxide layer, the titanium oxide layer has a relatively thin thickness and a relatively large refractive index, which has a large refractive index difference from a packaging layer, thereby can further improve the reflection effect and reduce light leakage on a front side of a semiconductor light-emitting device.

In an embodiment, as illustrated in FIG. 1, the semiconductor stack layer 300 has a mesa, and the mesa exposes the first semiconductor layer 310 and faces towards a side of the semiconductor stack layer 300 facing away from the substrate 200. A first electrode 500 and a second electrode 600 are formed on the semiconductor stack layer 300, the first electrode 500 is electrically connected to the first semiconductor layer 310, and the second electrode 600 is electrically connected to the second semiconductor layer 330. Specifically, the first electrode 500 is formed on the mesa and is in direct contact with the first semiconductor layer 310. A surface of the second semiconductor layer 330 is provided with a transparent conductive layer, such as an indium tin oxide layer or a GZO (gallium zinc oxide) layer, and the second electrode 600 is in direct contact with the transparent conductive layer.

The insulating layer 400 is located on the semiconductor stacking layer 300 and covers the first electrode 500, the second electrode 600 and the semiconductor stacking layer 300. The insulating layer 400 is provided with through holes corresponding to the first electrode 500 and the second electrode 600 respectively. The insulating layer 400 includes but is not limited to a single-layer structure or a distributed Bragg mirror. When the insulating layer 400 is the distributed Bragg mirror, a material of the insulating layer 400 is at least two of different materials such as SiO₂, TiO₂, ZnO₂, ZrO₂ and Cu₂O₃, and the insulating layer 400 specifically includes a distributed Bragg mirror made by alternately and repeatedly stacking two materials into multiple layers using a technique such as electron beam evaporation or ion beam sputtering.

A first pad 700 and a second pad 800 are located on the insulating layer 400 and are respectively connected to the first electrode 500 and the second electrode 600 through corresponding through holes. A material of each of the first pad 700 and the second pad 800 may be aluminum, chromium, nickel, titanium, platinum, tin, gold, or an alloy composed of at least two of these materials.

It should be noted that the disclosure does not specifically limit the structure of the flip-chip LED, and any structure with the optical thin film stacking layer 100 on the side of the substrate 200 should fall within the protection scope of the disclosure.

According to another aspect of the disclosure, a preparation method of a flip-chip LED is provided. The preparation method may include steps S1 to S5 as follows.

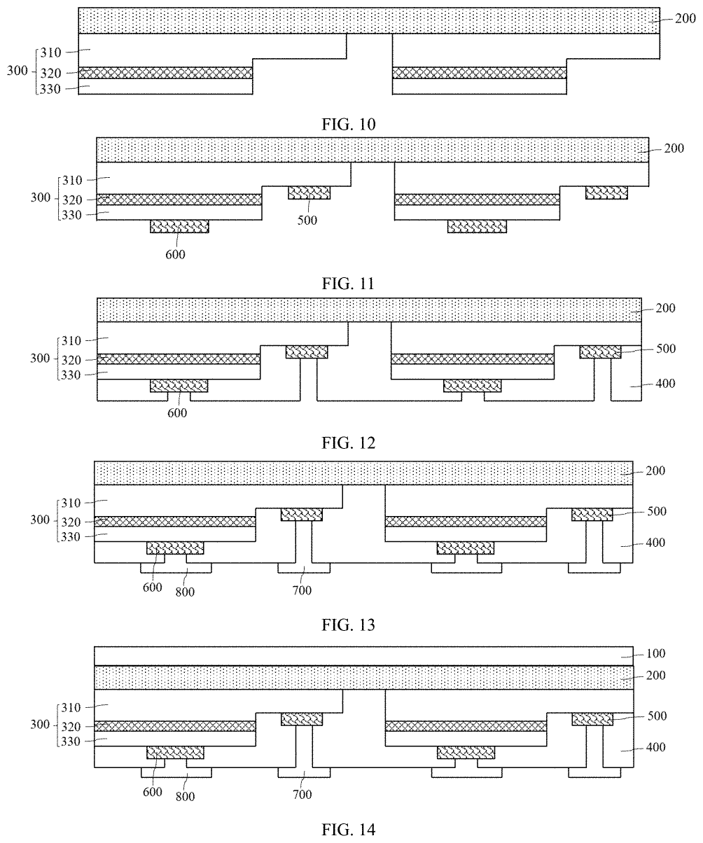

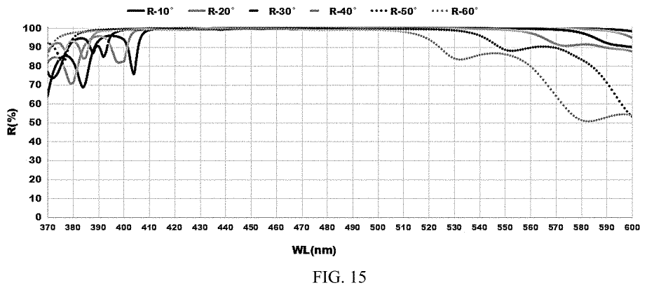

In step S1, as illustrated in FIG. 10, a substrate 200 is provided. The substrate 200 may be a transparent substrate and include but not be limited to a sapphire planar substrate or a sapphire patterned substrate. The substrate 200 has a first surface and a second surface opposite to the first surface, the first surface may refer to a lower surface of the substrate 200, and the second surface may refer to an upper surface of the substrate 200.

A plurality of semiconductor stacking layers 300 arranged at intervals are formed on the first surface of the substrate 200, and a cutting channel is formed between every adjacent two semiconductor stacking layers 300. Each semiconductor stacking layer 300 includes a first semiconductor layer 310, an active layer 320 and a second semiconductor layer 330 from top to bottom. In this embodiment, the first semiconductor layer 310 may be an N-type semiconductor layer, the second semiconductor layer 330 may be a P-type semiconductor layer, and the active layer 320 is a multiple quantum well layer and configured to emit light with a wavelength in a range of 420 nm to 480 nm.

Each semiconductor stacking layer 300 is further etched from the first surface, and a mesa exposing the first semiconductor layer 310 is formed on each semiconductor stack layer 300.

In step S2, as illustrated in FIG. 11, a first electrode 500 electrically connected to the first semiconductor layer 310 and a second electrode 600 electrically connected to the second semiconductor layer 330 are formed. The first electrode 500 is formed on the mesa and in direct contact with the first semiconductor layer 310. The second electrode 600 is formed on the second semiconductor layer 330 and in direct or indirect contact with the second semiconductor layer 330. A transparent conductive layer preferably is disposed between the second electrode 600 and the second semiconductor layer 330.

In step S3, as illustrated in FIG. 12, an insulating layer 400 is formed on the surface and side walls of each semiconductor stacking layer 300, and the insulating layer 400 is provided with through holes corresponding to the first electrode 500 and the second electrode 600 respectively. The insulating layer 400 includes, but is not limited to, a single-layer structure or a distributed Bragg mirror.

In step S4, as illustrated in FIG. 13, a first pad 700 and a second pad 800 are formed on the insulating layer 400. The first pad 700 is filled in the through hole corresponding to the first electrode 500 to electrically connect with the first electrode 500, and the second pad 800 is filled in the through hole corresponding to the second electrode 600 to electrically connect with the second electrode 600.

In step S5, as illustrated in FIG. 14, the substrate 200 is appropriately thinned to obtain a resultant thickness, and an optical thin film stacking layer 100 then is formed on the side of the substrate 200 where the second surface is located.

After completing the above steps S1 to S5, a stealth cutting process is applied onto the above resultant structure along the cutting channels to form independent flip-chip LEDs, each the independent flip-chip LED is the flip-chip LED shown in FIG. 1.

In the above cutting process, the LEDs to be cut are placed on a carrier, the optical thin film stacking layer 100 faces towards light sources of a cutting machine, and the light sources of the cutting machine include a first light source, a second light source and a third light source. The first light source is a light source for substrate thickness-wise position calibration, specifically is a laser light source in a wavelength range of 600 nm to 700 nm, and preferably is a laser light source with a center wavelength of 650 nm. The second light source is a light source for CCD imaging, specifically is a light source in a wavelength range of 800 nm to 900 nm, and preferably is a light source with a center wavelength of 850 nm. The third light source is a light source for stealth cutting inside the substrate, specifically is a laser light source in the wavelength range of 1000 nm to 1100 nm, and preferably is a laser light source with a center wavelength of 1064 nm.

Firstly, an image of the flip-chip LEDs is obtained by using the second light source to determine positions of transverse cutting channels and longitudinal cutting channels. Then, the laser emitted from the first light source radiates onto the substrate 200 at the positions of the transverse cutting channels and the longitudinal cutting channels from the top, a thickness of flip-chip LED is calculated according to the laser ranging principle, and dotting positions of laser on the substrate 200 then are determined according to the above calculated thickness. Finally, the laser emitted from the third light source is incident into the substrate 200 corresponding to the cutting channels to form cutting explosion points, and the substrate 200 is separated in pieces along the transverse cutting channels and the longitudinal cutting channels with the help of an external force to obtain individual flip-chip LEDs.

In a preferred embodiment, the optical thin film stacking layer 100 has a relatively large reflectivity to the light at 650 nm, the thickness of the flip-chip LED is calculated by using the 650 nm of laser, and the dotting positions of laser on the substrate 200 are then determined according to the above calculated thickness, thereby can ensure the consistency of the dotting positions of laser on the substrate 200.

In a preferred embodiment, the reflectivity of the optical thin film stacking layer 100 to the light at 850 nm is less than or equal to 60%, which facilitates the light at 850 nm to pass through the optical thin film stacking layer 100 and then obtain the image of the semiconductor stacking layer 300 and electrode structures on the other side of the substrate 200.

In a preferred embodiment, the reflectivity of the optical thin film stacking layer 100 to the light at 1064 nm is less than or equal to 10%, which facilitates the laser at 1064 nm to pass through the optical thin film stacking layer 100 and then reach the interior of the substrate 200 for cutting.

According to still another aspect of the disclosure, a semiconductor light-emitting device is provided. As illustrated in FIG. 9, the semiconductor light-emitting device may include a packaging substrate 1000, at least one flip-chip LED 2000 according to the above embodiments arranged on the packaging substrate 1000, and a packaging layer 3000. The packaging layer is disposing covering sidewalls of the flip-chip LED 2000. The structure of the flip-chip LED 2000 may be the same as that of the flip-chip LED in the above embodiments, and thus will not be repeated herein.

The packaging substrate 1000 may be a planar type, or the packaging substrate 1000 has a reflective cup surrounding the flip-chip LED 2000. The reflective cup defines a space for accommodating the flip-chip LED 2000. A surface of the packaging substrate 1000 for mounting the flip-chip LED 2000 may include a metal electrode layer 1100, and the metal electrode layer 1100 includes a first metal electrode layer and a second metal electrode layer with different polarities. The first pad 700 of the flip-chip LED 2000 is connected to the first metal electrode layer, and the second pad 800 of the flip-chip LED 2000 is connected to the second metal electrode layer.

A refractive index of the packaging layer 3000 is different from that of the optical thin film stacking layer 100. The packaging layer 3000 may include but not be limited to silicone, and a refractive index of silicone is in a range from 1.41 to 1.53.

As can be seen from the above technical solutions, the optical thin film stacking layer 100 is arranged on the side of the substrate 200 facing away from the semiconductor stacking layer 300. The optical thin film stacking layer 100 includes the first reflective film group 10, and the first reflective film group 10 includes the repeatedly stacked first material layer 11 and second material layer 12 and is used to reflect the light emitted from the semiconductor stacking layer 300. The first reflective film group 10 has a relatively large reflectivity for the small angle output light and a relatively small reflectivity for the large angle output light, thereby can realize the reflection of the small angle output light and partial transmission of the large angle output light, and thus can effectively improve the brightness of the flip-chip LED or the semiconductor light-emitting device. For example, the small angle refers to 0° to 20°, and the large angle refers to 40° to 60°.

In addition, the first material layer 11 may be the titanium oxide layer, the second material layer 12 may be the silicon oxide layer, the optical thicknesses of the first material layer 11 and the second material layer 12 each are relatively small, and the total layer number of the first material layer 11 and the second material layer 12 preferably is less than 15.

Moreover, the optical thin film stacking layer 100 may further include the second reflective film group 20, and the second reflective film group 20 is located on the side of the first reflective film group 10 facing away from the substrate 200. The second reflective film group 20 may include the repeatedly stacked third material layer 21 and fourth material layer 22. The third material layer 21 may be the silicon oxide layer and the fourth material layer 22 may be the titanium oxide layer, and the number of the third material layer 21 or the fourth material layer 22 may be of 2 to 5 layers. The reflectivity of the second reflective film group 20 to the first light may be higher than 50%, and the wavelength of the first light may be in the range from 600 nm to 700 nm. The reflectivity of the second reflective film group 20 to the second light may be less than 60%, and the wavelength of the second light may be in the range from 800 nm to 900 nm. The reflectivity of the second reflective film group 20 to the third light may be less than 10%, and the wavelength of the third light may be in the range from 1000 nm to 1100 nm. Since the second reflective film group 20 has the relatively large reflectivity to the light at 650 nm, which facilitates to use the 650 nm of laser to accurately position dotting positions of the laser on the substrate 200 in the stealth cutting process, thereby can improve the accuracy of the stealth cutting process. Furthermore, since the second reflective film group 20 has a relatively small reflectivity to the light at 850 nm, which facilitates the light at 850 nm to pass through the optical thin film stacking layer 100 to obtain the image of the semiconductor stacking layer 300 and the electrode structures on the other side of the substrate 200. Since the second reflective film group 20 has the relatively small reflectivity to the light at 1064 nm, which facilitates the 1064 nm of laser to pass through the optical thin film stacking layer 100 and reach the interior of the substrate 200 for cutting.

What is claimed is:

1. A flip-chip light-emitting diode (LED), comprising:
a substrate, having a first surface and a second surface opposite to the first surface;
a semiconductor stacking layer, formed on the first surface and configured to radiate light; and
an optical thin film stacking layer, formed on the second surface;
wherein the optical thin film stacking layer comprises a first reflective film group, and the first reflective film group comprises a first material layer and a second material layer repeatedly stacked;
wherein optical thicknesses of the first material layer and the second material layer meet conditions that: the optical thin film stacking layer is configured to reflect a light with a wavelength in a range of 420 nm to 480 nm emitted from the semiconductor stacking layer and at an incident angle being a first angle, and partially transmit the light at an incident angle being a second angle, and the first angle being smaller than the second angle.

2. The flip-chip LED according to claim 1, wherein a reflectivity of the first reflective film group to the light at the first angle with the wavelength in the range of 420 nm to 480 nm is greater than that of the first reflective film group to the light at the second angle with the wavelength in the range of 420 nm to 480 nm.

3. The flip-chip LED according to claim 1, wherein the first reflective film group is configured to reflect a light with a wavelength in a range of 440 nm to 455 nm at the first angle, and partially transmit a light with a wavelength in the range of 440 nm to 455 nm at the second angle.

4. The flip-chip LED according to claim 1, wherein the first angle is in a range of 0° to 20°, and the second angle is in a range of 40° to 60°.

5. The flip-chip LED according to claim 4, wherein a reflectivity of the first reflective film group to the light at the first angle with the wavelength in the range of 420 nm to 480 nm is greater than 90%, and a reflectivity of the first reflective film group to at least part of the light at the second angle with the wavelength in the range of 420 nm to 480 nm is less than 90%.

6. The flip-chip LED according to claim 1, wherein an optical thickness of the first material layer is λ₁/4, and 300 nm≤λ₁≤480 nm.

7. The flip-chip LED according to claim 1, wherein an optical thickness of the second material layer is λ₂/4, and 350 nm≤λ₂≤520 nm.

8. The flip-chip LED according to claim 1, wherein a geometric thickness of the first material layer is smaller than that of the second material layer.

9. The flip-chip LED according to claim 1, wherein the first material layer is a titanium oxide layer, and a geometric thickness of the first material layer is in a range of 30 nm to 50 nm.

10. The flip-chip LED according to claim 1, wherein the second material layer is a silicon oxide layer, and a geometric thickness of the second material layer is 60 nm to 100 nm.

11. The flip-chip LED according to claim 1, wherein a total layer number of the first material layer and the second material layer in the first reflective film group is odd, and the total layer number is less than 15.

12. The flip-chip LED according to claim 1, wherein the optical thin film stacking layer further comprises:
a second reflective film group, disposed on a side facing away from the second surface of the first reflective film group, wherein the second reflective film group comprises a third material layer and a fourth material layer repeatedly stacked, and optical thicknesses of the third material layer and the fourth material layer meet conditions that: a reflectivity of the second reflective film group to a first light is greater than 50%, a reflectivity of the second reflective film group to a second light is less than 60%, a reflectivity of the second reflective film group to a third light is less than 10%, a wavelength of the first light is in a range of 600 nm to 700 nm, a wavelength of the second light is in a range of 800 nm to 900 nm, a wavelength of the third light is in a range of 1000 nm to 1100 nm, and incident angles of the first light, the second light and the third light each are in a range of 0° to 10°.

13. The flip-chip LED according to claim 12, wherein the optical thickness of the third material layer is λ₃/4, and 450 nm≤λ₃≤900 nm.

14. The flip-chip LED according to claim 12, wherein the optical thickness of the fourth material layer is λ₄/4, and 300 nm≤λ₄≤900 nm.

15. The flip-chip LED according to claim 12, wherein a total layer number of the third material layer and the fourth material layer in the second reflective film group is even, and a layer number of the fourth material layer in the second reflective film group is in a range of 2 to 5.

16. The flip-chip LED according to claim 12, wherein a reflectivity of the second reflective film group to light at 650 nm is greater than or equal to 50%, a reflectivity of the second reflective film group to light at 850 nm is less than or equal to 60%, and a reflectivity of the second reflective film group to light at 1064 nm is less than or equal to 10%.

17. A flip-chip LED, comprising:
a substrate, having a first surface and a second surface opposite to the first surface;
a semiconductor stacking layer, formed on the first surface and configured to radiate light; and
an optical thin film stacking layer, formed on the second surface;
wherein the optical thin film stacking layer comprises a first reflective film group and a second reflective film group, the second reflective film group is disposed on a side of the first reflective film group facing away from the second surface;
wherein the first reflective film group comprises a first material layer with a relatively high refractive index and a second material layer with a relatively low refractive index repeatedly stacked;
wherein the second reflective film group comprises a third material layer with a relatively low refractive index and a fourth material layer with a relatively high refractive index are repeatedly stacked; and
wherein a geometric thickness of each the second material layer with the relatively low refractive index in the first reflective film group is smaller than that of each the third material layer with the relatively low refractive index in the second reflective film group.

18. The flip-chip LED according to claim 17, wherein a sum of the geometric thicknesses of the second material layers in the first reflective film group is smaller than a sum of the geometric thicknesses of the third material layers in the second reflective film group.

19. The flip-chip LED according to claim 17, wherein an optical thickness of the first material layer is λ₁/4, and 300 nm≤λ₁≤480 nm; and/or
wherein an optical thickness of the second material layer is λ₂/4, and 350 nm≤λ₂≤520 nm.

20. A semiconductor light-emitting device comprising:
a packaging substrate;
a flip-chip LED, arranged on the packaging substrate; and
a packaging layer, disposing covering sidewalls of the flip-chip LED;
wherein the flip-chip LED comprises:
a substrate, having a first surface and a second surface opposite to the first surface;
a semiconductor stacking layer, formed on the first surface and configured to radiate light; and
an optical thin film stacking layer, formed on the second surface;
wherein the optical thin film stacking layer comprises a first reflective film group, and the first reflective film group comprises a first material layer and a second material layer repeatedly stacked;
wherein optical thicknesses of the first material layer and the second material layer meet conditions that: the optical thin film stacking layer is configured to reflect a light with a wavelength in a range of 420 nm to 480 nm emitted from the semiconductor stacking layer and at an incident angle being a first angle, and partially transmit a light at an incident angle being a second angle, and the first angle being smaller than the second angle.
